(19) United States
(12) Patent Application Publication
(10) Pub. No.: US 2009/0080486 A1
(43) Pub. Date: Mar. 26, 2009

(54) Laser Device Using an Inorganic Electro-Luminescent Material Doped With a Rare-Earth Element

(76) Inventor: Young-Gu Ju, Buk-gu (KR)

Correspondence Address: MCNEELY BODENDORF LLP, P.O. BOX 34175, WASHINGTON, DC, 20043, US

(21) Appl. No.: 12/036,286

(22) Filed: Feb. 24, 2008

(30) Foreign Application Priority Data
Apr. 23, 2007 (KR) 10-2007-0039205

(51) Int. Cl. H01S 5/00

(52) U.S. Cl. 372/50.11

(57) ABSTRACT

A laser device using an inorganic electro-luminescent material doped with a rare-earth element is provided. A dielectric layer such as SiO₂ is arranged on a silicon substrate. A polycrystalline thin film of Er-doped ZnS or ZnSe is arranged on the dielectric layer. An electrode is formed on the dielectric layer. After a waveguide structure is substantially formed, a reflector is formed at both ends of the waveguide structure to form a laser resonator. An active medium is a polycrystalline material of Er-doped ZnS or ZnSe. When an AC voltage is applied between an electrode attached to the substrate and an electrode attached to an uppermost part, the effect of emitting light at 1550 nm and generating population inversion is used.

### CLAIM OF PRIORITY

This application makes reference to and claims all benefits accruing under 35 U.S.C. §119 from an application for “LASER DEVICE USING AN INORGANIC ELECTRO-LUMINESCENT MATERIAL DOPED WITH RARE-EARTH METAL,” earlier filed in the Korean Intellectual Property Office on Apr. 23, 2007 and there duly assigned Serial No. 2007-0038205.

### BACKGROUND OF THE INVENTION

1. Field of the Invention

The present invention relates to a semiconductor laser device, and more particularly to a laser device using an inorganic electro-luminescent (EL) material doped with a rare-earth element.

2. Description of the Related Art

At present, a silicon (Si) semiconductor process technology is precise enough to implement a line width as small as 50 nm, which is the motive of improving the degree of integration and speed. A highly integrated chip may be produced at low cost on the basis of a large-sized wafer processing technology. Recently, an attempt is being made to manufacture optical devices using the silicon process technology having advantages of high integration, high speed, and low cost.

Silicon photonics is being developed by classifying basic components into a light source, waveguide, modulator, photo detector, low-cost assembly, and artificial intelligence.

Currently, the waveguide adopts a silicon waveguide. An attempt is being made to secure a low-cost assembly process along with a passive arrangement of an optical fiber using a taper tip structure. The modulator exhibits the bandwidth performance of 1 GHz or more in a Mach-Zehnder type. In terms of the photo detector, a method using a SiGe detector is being tested. It is expected that a device operable at about 10 Gbps may be manufactured through modeling.

In manufacturing various optical elements to be used in the silicon photonics, the light source may be problematic. Basically, the silicon may not emit light since the silicon has an indirect band gap. To avoid a structural problem of the silicon, porous silicon, Er-doped nano-crystal silicon, and the like are being used for the light source.

The porous silicon has a serious drawback in reproducibility and reliability of a luminescent device because of high reactivity in a sponge structure. While the Er-doped nano-crystal silicon currently being actively researched has been further improved in comparison with the silicon, its optical conversion efficiency is lower (several tens of times to several hundreds of times) than that of a compound semiconductor.

On the other hand, a Raman silicon laser is recently being used for a silicon light source. This laser should have an external high-power pumping laser coupled into a silicon waveguide. In this case, the advantages obtained from using the silicon photonics disappear. This is because a device price can be determined by a laser diode (LD) for pumping. Since this method should externally integrate a special LD chip, the packaging cost also increases.

Flip-chip bonding Fabry-Perot (FP) LDs or Vertical Cavity Surface Emitting Lasers (VCSELs) on the silicon substrate can be simpler than making the Raman silicon laser. An optical pumping method using a compound semiconductor light source is also tried in a method using a GaN light-emitting diode (LED) as a light source for pumping. This is disadvantageous in manufacturing an optical communication device in comparison with a method of bonding III-V light source chips to a silicon semiconductor. Even though the attachment of devices having heterogeneous materials is not problematic with the development of a device packaging method, it is still avoided due to the increased cost and poor scalibility.

If an optical device for emitting light through electric pumping is not made in the silicon itself, additional chips should be attached in proportion to the number of channels. For this reason, the existing methods are difficult to take full advantage of a mass production technology developed for a silicon semiconductor device, thereby resulting in an increase in cost.

### SUMMARY OF THE INVENTION

The invention has been made to solve the foregoing problems of the prior art and therefore an object of the invention is to provide a laser device using an inorganic EL material doped with a rare-earth element that can be fabricated on a silicon substrate (or glass substrate) using an inorganic EL material and that can provide a long-wavelength light source in which electric pumping is possible.

According to an aspect of the invention, there is provided a laser device using an inorganic electro-luminescent material doped with a rare-earth element, including: a dielectric layer arranged on a substrate; an active medium core arranged in the dielectric layer, the active medium core being formed by doping erbium into a chalcogenide material; and first and second electrodes formed to face each other such that an electric field is generated in the active medium core and the dielectric layer, wherein the active medium core and the dielectric layer form a waveguide structure and a reflector is formed at both ends of the waveguide structure to form a resonator.

Preferably, when the substrate is a silicon substrate, the first electrode is formed in a lower part of the silicon substrate and the second electrode is formed on the dielectric layer. Preferably, when the substrate is a glass substrate, the first electrode serving as a transparent electrode is arranged between the glass substrate and the dielectric layer and the second electrode is arranged on the dielectric layer.

Preferably, the chalcogenide material is at least one of ZnS and ZnSe. Preferably, the reflector is a distributed Bragg reflector (DBR) using a grating pattern or a multi-layered thin film having high reflectance. Preferably, the dielectric layers are connected with each other to surround an active medium.

### BRIEF DESCRIPTION OF THE DRAWINGS

The above and other objects, features and other advantages of the invention will be more clearly understood from the following detailed description taken in conjunction with the accompanying drawings, in which:

FIG. 1 is a schematic cross-sectional view of a laser device using an inorganic EL material doped with a rare-earth element according to a first exemplary embodiment of the invention;

FIG. 2 is a schematic cross-sectional view of a laser device using an inorganic EL material doped with a rare-earth element according to a second exemplary embodiment of the invention; and

FIG. 3 is a schematic perspective view of a laser device using an inorganic EL material doped with a rare-earth element according to an exemplary embodiment of the invention.

### DETAILED DESCRIPTION OF EXEMPLARY EMBODIMENTS

Exemplary embodiments of the invention now will be described more fully with reference to the accompanying drawings, in which exemplary embodiments of the invention are shown. This invention may, however, be embodied in many different forms and should not be construed as limited to the exemplary embodiments set forth herein. In the drawings, elements that are not directly related to the description of the invention are omitted for convenience of explanation. Like reference numerals refer to like elements throughout this application.

In addition, unless explicitly described to the contrary, the word “comprise” and variations such as “comprises” or “comprising” will be understood to imply the inclusion of stated elements but not the exclusion of any other elements. In addition, the word “part”, “unit”, “module”, “block”, or the like will be understood to indicate a unit for processing at least one function or operation, which may be realized by hardware, software, or a combination thereof.

Now, a laser device using an inorganic EL material doped with a rare-earth element according to the exemplary embodiments of the invention will be described with reference to the accompanying drawings in detail.

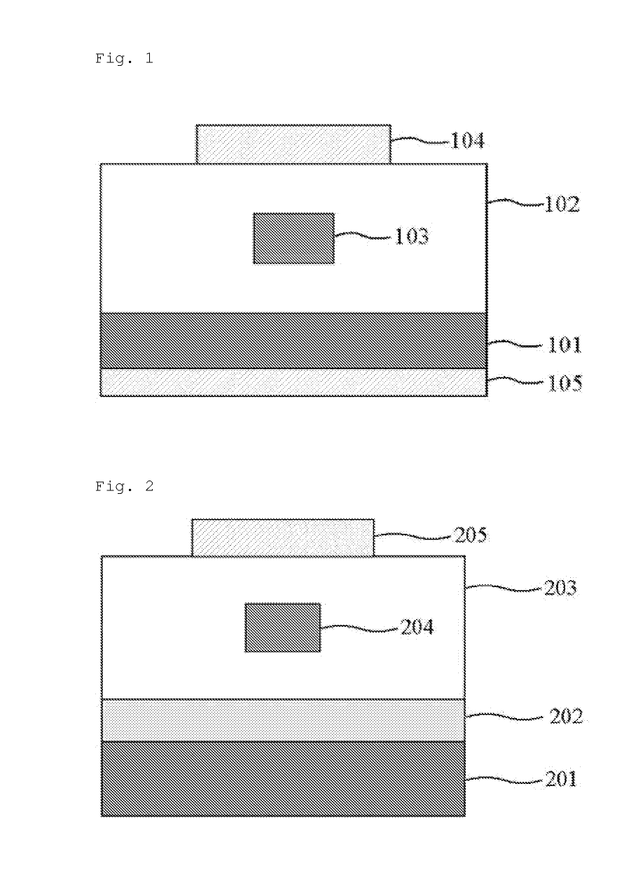

FIG. 1 is a schematic cross-sectional view of a laser device using an inorganic EL material doped with a rare-earth element according to a first exemplary embodiment of the invention.

In the luminescent laser device according to the first exemplary embodiment of the invention as shown in FIG. 1, a dielectric layer 102 is layered on a silicon substrate 101, a laser active medium 103 is formed in the dielectric layer 102, and electrodes 104 and 105 are respectively formed on the dielectric layer 102 and the silicon substrate 101. Herein, the dielectric layer 102 and the active medium 103 substantially form a waveguide structure. In this case, the active medium 103 corresponds to a core in the waveguide structure.

When the silicon substrate 101 is n or p doped, the conductivity is superior. Accordingly, an electric field is applied to the dielectric layer 102 when an alternating current (AC) voltage is applied to the electrodes 104 and 105.

The dielectric layer 102 can use an insulator such as SiO₂ capable of being deposited in a method of chemical vapor deposition (CVD), flame hydrolysis deposition (FHD), or the like and serving as a material constituting a cladding of a silica optical device. Advantageously, a light source and other passive optical devices can be monolithically integrated using the same process as in the method using the silica optical device.

The active medium 103 is formed by depositing an EL chalcogenide material such as ZnS or ZnSe and Er serving as one of rare-earth elements in the form of a thin film, heating the resulting film, and forming a polycrystalline thin film. Er-doped ZnS exhibits a narrow linewidth spectrum at 1550 nm when an AC electric field is applied to each of the electrodes 104 and 105. This active medium 103 has an optical waveguide structure capable of being variously implemented with a technique used to manufacture an existing semiconductor laser. Once the ZnS or ZnSe layer is deposited, a waveguide pattern is formed using optical lithography and its side is filled with a dielectric material, such that the optical waveguide structure can be formed.

The laser active medium 103 of the luminescent laser device according to the first exemplary embodiment of the invention has the effect of an optical amplification medium formed by doping Er into an existing silica or polymer material. The existing amplifier such as an Er-doped silica amplifier requires an LD for external pumping to achieve laser population inversion in the existing silica or polymer material. An inorganic EL material (that is, ZnS) doped with Er has an electric pumping structure for emitting light by applying an AC voltage to an electrode.

When the AC voltage is applied to the two electrodes 104 and 105, the electric field is formed in the dielectric layer 102 by the applied AC voltage. The electric field varies with the polarity of the AC voltage. At this time, the electric field accelerates electrons in the laser active medium 103, that is, ZnS or ZnSe, such that energy is supplied and light is emitted at 1550 nm. Consequently, the invention as described above can provide a 1550 nm laser light source in which electric pumping is possible.

Next, a luminescent laser device according to a second exemplary embodiment of the invention will be described with reference to FIG. 2. FIG. 2 is a schematic cross-sectional view of a laser device using an inorganic EL material doped with a rare-earth element according to the second exemplary embodiment of the invention.

The luminescent laser device is implemented on the silicon substrate 101 in the luminescent laser device according to the first exemplary embodiment of the invention, whereas the luminescent laser device is implemented on a glass substrate in the luminescent laser device according to the second exemplary embodiment of the invention.

Specifically, in the luminescent laser device according to the second exemplary embodiment of the invention, a transparent electrode 202 is deposited on a glass substrate 201, a dielectric layer 203 is deposited on the transparent electrode 202, a laser active medium 204 is formed in the dielectric layer 203, and an electrode 205 is formed on the dielectric layer 203 to face the transparent electrode 202. The dielectric layer 203 and the active medium 204 substantially form a waveguide structure. In this case, the active medium 204 corresponds to a core in a waveguide.

As in the first exemplary embodiment, the laser active medium 204 is formed by depositing an EL chalcogenide material such as ZnS or ZnSe and Er serving as one of rare-earth elements in the form of a thin film, heating the resulting film, and forming a polycrystalline thin film.

Therefore, the laser active medium 204 has the effect of an optical amplification medium formed by doping Er into an existing silica or polymer material.

The dielectric layer 203 can use an insulator such as SiO₂.

The transparent electrode 202 is deposited on the glass substrate 201 since the glass substrate 201 is a nonconductor.

When the AC voltage is applied to the transparent electrode 202 and the electrode 205, the electric field is applied to the dielectric layer 203. At this time, a varied electric field accelerates electrons in the laser active medium 204, that is, ZnS or ZnSe, such that light is emitted at 1550 nm.

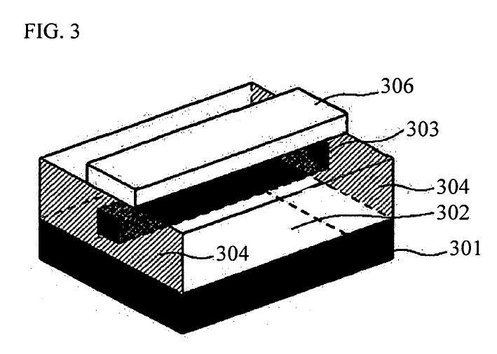

Next, a luminescent laser device according to an exemplary embodiment of the invention will be described with reference to FIG. 3. FIG. 3 is a schematic perspective view of a laser device using an inorganic EL material doped with a rare-earth element according to the exemplary embodiment of the invention.

The invention has been described with reference to the first and second exemplary embodiments in which the waveguide is constituted with the dielectric layer 102 or 203 and the active medium 103 or 204 and the electrodes 104 and 105 or 202 and 205 are formed.

In the invention as shown in FIG. 3, a reflector 304 is formed on a cross section of a dielectric layer making contact with both end parts of a waveguide, thereby forming a laser resonator. This reflector 304 can use an etched surface as in an existing semiconductor laser. When the loss of light is reduced by increasing reflectance through multi-layered thin film coating, a threshold current value can be reduced. Alternatively, the reflector 304 can be implemented by forming a grating pattern on a surface as in a distributed Bragg reflector (DBR) or including a waveguide structure.

The invention can be used to form an optical integrated circuit with a passive optical device such as an existing silica optical waveguide or filter since an electric pumping type long-wavelength light source can be integrated on a glass substrate or silicon substrate. Moreover, the invention can implement an intelligent optical device along with a Si electronic device.

While the invention has been shown and described in connection with the preferred embodiments, it will be apparent to those skilled in the art that modifications and variations can be made without departing from the spirit and scope of the invention as defined by the appended claims.

What is claimed is:

1. A laser device using an inorganic electro-luminescent material doped with a rare-earth element, comprising:
a dielectric layer arranged on a substrate;
an active medium core arranged in the dielectric layer, the active medium core being formed by doping erbium into a chalcogenide material; and
first and second electrodes formed such that an electric field is generated in the active medium core and the dielectric layers, wherein the active medium core and the dielectric layers form a waveguide structure and a reflector is formed at both ends of the waveguide structure to form a resonator.

2. The laser device according to claim 1, wherein when the substrate is a silicon substrate, the first electrode is formed in a lower part of the silicon substrate and the second electrode is formed on the dielectric layer.

3. The laser device according to claim 1, wherein when the substrate is a glass substrate, the first electrode serving as a transparent electrode is arranged between the glass substrate and the dielectric layer and the second electrode is arranged on the dielectric layer.

4. The laser device according to claim 1, wherein the chalcogenide material is at least one of ZnS and ZnSe.

5. The laser device according to claim 4, wherein the reflector is a distributed Bragg reflector using a grating pattern.

6. The laser device according to claim 4, wherein the reflector is a multi-layered thin film having high reflectance.

7. The laser device according to claim 4, wherein the dielectric layers are unified to seal an active medium.
